(19) United States
(12) Patent Application Publication
(10) Pub. No.: US 2006/0071301 A1
(43) Pub. Date: Apr. 6, 2006

(54) Silicon rich dielectric antireflective coating

(76) Inventors: Shing Ann Luo, Hsinchu (TW); Chin Ta Su, Hsinchu (TW)

Correspondence Address: KNOBBE MARTENS OLSON & BEAR LLP, 2040 MAIN STREET, FOURTEENTH FLOOR, IRVINE, CA, 92614, US

(21) Appl. No.: 10/959,589

(22) Filed: Oct. 6, 2004

(51) Int. Cl. H01L 23/58

(52) U.S. Cl. 257/632

(57) ABSTRACT

A light absorption layer for use in fabricating semiconductor devices is provided with a high Si concentration. For example, a semiconductor device comprises a substrate and an Si-rich dielectric light absorption layer, such as an SiON or SiOX layer having an Si concentration of at least 68%. A second dielectric antireflective coating layer is optionally formed over the Si-rich dielectric light absorption layer.

### BACKGROUND OF THE INVENTION

1. Field of the Invention

The present invention relates to semiconductor devices, and in particular to light absorption layers for use in fabricating semiconductor devices.

2. Description of the Related Art

In current conventional semiconductor manufacturing, in order to prevent light reflection from being transmitted through the photo-resist, reflected off the substrate and back into the photoresist, where it can interfere with incoming light and so result in the uneven exposure of the photoresist, conventionally one or more antireflective layers may be deposited before the photoresist is deposited or spun on. The antireflective layers may be organic or inorganic.

For example, in the absence of an antireflection coating, interference of reflected and incident exposure radiation can cause standing wave effects that distort the uniformity of the radiation at different points in the photoresist layer. Such lack of uniformity can lead to undesirable line width variation.

### SUMMARY OF THE INVENTION

The present invention relates to semiconductor devices, and in particular to antireflective coatings (ARCs) for use in semiconductor devices.

In one embodiment, a silicon oxynitride (SiON) film, such as a Super-Si Rich SiON film, or a silicon oxide (SiOX) film, such as a Super-Si Rich SiOX film, is used to form an absorption layer or film that optionally advantageously acts as an etch stop layer or hard mask. Optionally, the Super-Si Rich SiOX film can act as a bottom layer in a dual antireflective coating stack.

By way of further example, one embodiment provides a semiconductor device, comprising: a substrate; an Si rich dielectric light absorption layer having an Si concentration of at least 68%; and a dielectric antireflective coating layer.

Another embodiment provides a semiconductor device, comprising: a substrate; and a dielectric light absorption layer having an Si concentration of at least 70%.

Still another embodiment provides a method of fabricating a semiconductor device, comprising: forming a semiconductor structure; forming an Si-rich light absorption layer having an Si concentration of at least 68%; forming a photoresist layer over the Si-rich light absorption layer; exposing the photoresist layer to form a first photoresist opening; forming an opening in the Si-rich light absorption layer through the photoresist opening; and filling the Si-rich light absorption layer opening with a conductor.

### BRIEF DESCRIPTION OF THE DRAWINGS

FIG. 1 illustrates an example DARC stack including an example film in accordance with an embodiment of the present invention.

FIG. 2A depicts a graph illustrating reflectivity as a function of thickness for an example dual DARC implementation.

FIGS. 2B-C provide graphs of example concentrations of different atoms as a function of depth.

FIG. 3 provides an example graph illustrating resist feature width as a function of resist thickness, which can be used to select the swing ratio and desired photoresist thickness.

FIGS. 4A-B depict graphs of light transmission through DARC and SSDARC films.

FIG. 5 illustrates example process states in the formation of a contact profile on SSDARC.

FIG. 6 illustrates an example fabrication process.

### DETAILED DESCRIPTION OF THE PREFERRED EMBODIMENTS

The present invention relates to semiconductor devices, and in particular to antireflective coatings (ARCs) and etch stop layers for use in fabricating semiconductor devices.

In one embodiment, a silicon oxynitride (SiON) film, such as a Super-Si Rich SiON film, or a silicon oxide (SiOX) film, such as a Super-Si Rich SiOX film, is used to form an absorption layer or film that optionally advantageously acts as an etch stop layer or hard mask and can prevent an underlying layer from being damaged or scratched during chemical and/or mechanical polishing and planarization.

The Super-Si Rich SiON or Oxide layers reduce reflection because the extinction coefficient and refractive index increase with an increase in the silicon content of the SiON or SiOX layer. The Super-Si Rich SiON or Oxide layer can thus act as an absorption DARC (dielectric antireflective coating) film or layer (also referred to herein as a Super-Si DARC or SSDARC layer), and can optionally form a part of a dual DARC stack, such as the bottom layer in the dual DARC stack, wherein the top layer is optionally a non-super Si rich DARC layer. The non-super Si rich DARC layer can act as a destructive interference layer. By way of example, the dual DARC layers can reduce standing waves and reflective notching from substrate reflections or phase shifts, such as may occur during photolithography exposure.

In particular, the Si-rich DARC film advantageously absorbs incident light, including, for example, ultraviolet (UV, with wavelengths of 400 nm-10 nm), deep ultraviolet, and/or visible light (with wavelengths of 750-400 nm), to thereby reduce or minimize light reaching the substrate, and hence reduce reflectance from the substrate. For example, the absorbed incident light can have a wavelength of approximately 248 nm, such as that used by many exposure systems that employ Krypton Fluoride excimer lasers. In one embodiment, the absorbed incident light can have a wavelength of approximately 193 nm. Excellent photo performance can be achieved, with reduced interference effects and a low swing ratio of valleys to peaks, such as a swing ratio of 14%-11% or less.

Further, enhanced critical dimension (CD) uniformity, and a relatively larger process margin is achieved. In addition, the Super-Si Rich SiON or Oxide film provides a high k (extinction coefficient) value. For example, in one embodiment the film has an extinction coefficient within the range of 1.68 to 1.72, or optionally an extinction coefficient generally greater than 1.7, such as approximately 1.71, 1.73, 1.75, and so on.

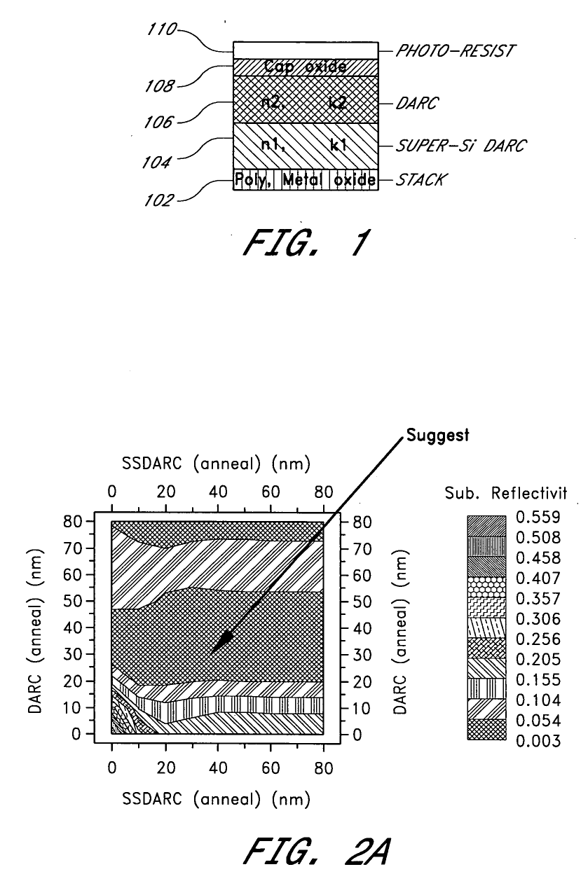

FIG. 1 illustrates an example semiconductor device with a dual DARC stack including an SSDARC layer. In particular, a stack 102 includes, by way of example, polysilicon, metal interconnect and/or gate oxide feature or layers formed on a substrate. An inorganic SSDARC layer 104 is formed on the stack 102. The SSDARC layer 104 acts as a bottom absorption layer. An optional inorganic DARC layer 106, having a lower Si concentration than the SSDARC layer 104, acts as an antireflection destructive interference layer. A cap oxide layer 108 is formed over the DARC layer 106. Photoresist 110 overlays the cap oxide layer 108. Other embodiments optionally include just the SSDARC layer without the DARC layer having the conventional Si concentration.

The SiON or SiOX DARC layer can be deposited using chemical vapor deposition (CVD) or plasma enhanced chemical vapor deposition. For example, the SiON or SiOX layer can be deposited on an ILD (Inter-layer dielectric) or a IMD (Inter-metal dielectric), which in turn are formed over a dielectric, device structure, substrate or another layer. The SiON or SiOX layer thickness can be selected and formed as needed for the desired application. For example, different corresponding thicknesses can be used for STI (shallow trench isolation), ILD, or IMD applications. The SSDARC thickness can optionally be selected so as to reduce the reflectivity as much as possible for a given process.

As similarly discussed above, advantageously, the Super-Si Rich SiON or Oxide film or ARC has a relatively higher etch selectivity to photoresist and so advantageously acts as an etch stop layer with a low etching rate, such as when etching a polysilicon or silicon substrate. Because the Super-Si Rich SiON or Oxide film etches significantly slower than the resist, more SSDARC is preserved, resulting in enhanced maintenance of the dimension integrity.

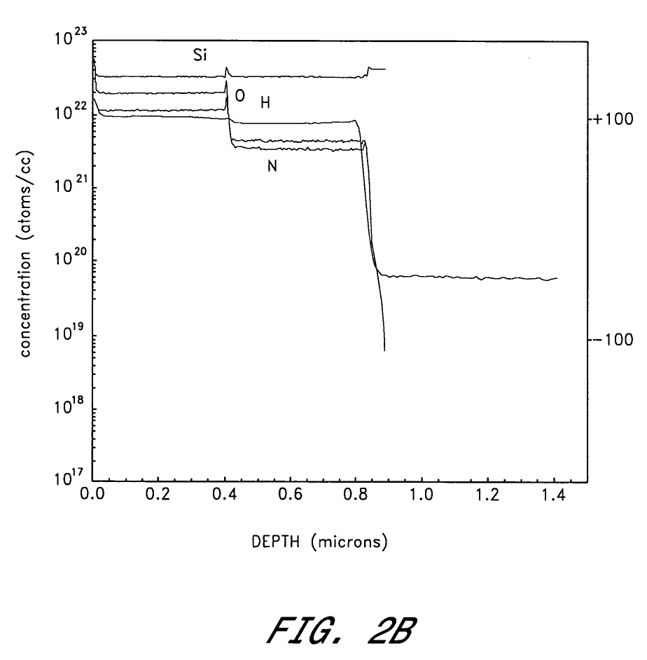

FIG. 2A depicts a graph illustrating Sub Reflectivity (the reflectivity of the interface underlying the photoresist) for an example dual DARC implementation. The reflectivity is graphed as a function of SSDARC and DARC thickness for an example semiconductor device for a given k (extinction coefficient) and n (index of refraction). For example, in one embodiment, for the DARC film, n=2.169, k=0.438; for the SSDARC film, n=1.97, k=1.7. Other embodiments can have other values of n and k. In this example, the Sub Reflectivity is generally controlled to less than 1%, and the reflectivity is reduced to 0.003 or less when the dual DARC films are utilized.

FIGS. 2B-C provide graphs of example concentrations of different atoms as a function of depth, wherein FIG. 2B shows concentrations in units of atoms/cc for Si/O/H/N and FIG. 2C shows concentrations for Si/O/C/F/Cl. The illustrated graphs were generated utilizing a secondary ion mass spectroscopy (SIMS) analysis of an example sample. The measurement was performed using a Cs⁺ and O₂⁺ primary ion source and measuring the positive secondary ion, respectively. The resulting measurements show atoms concentrations, respectively. As illustrated, the Si/O concentration quantity are the same in the two graphs. Additional remark depth from 0 um to 0.4 um was SSDARC; depth from 0.4 um to 0.8 um was conventional DARC.

The Si-rich DARC layer also advantageously provides improved resolution and enhanced critical dimension (CD) control. The CD line width control can provide, by way of example, a CD variation@photoresist of approximately ±100 Å: CD variation@PR ±100 Å is approximately 4 nm. The CD variation of photoresist is under ±100 Å when a borophosphosilicate glass (BPSG) film is introduced. Other embodiments can have different CD variations.

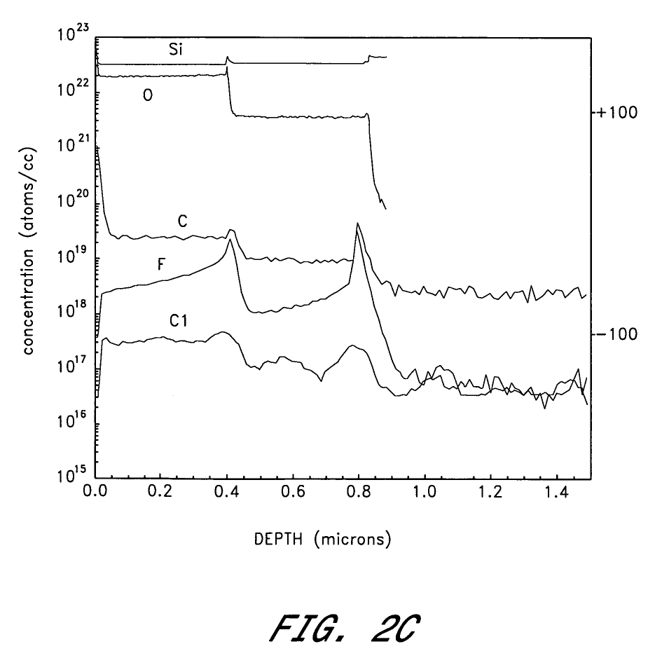

FIG. 3 depicts a graph illustrating the swing ratio as a function of photoresist thickness and resist feature width (CD). In the illustrated example, a photoresist thickness of 460 nm provides a swing ratio of only 11%. Other photoresist thicknesses can be used as well, such as thicknesses within the range of 440 nm to 480 nm, within the range of 400 nm to 440 nm, or within the range of 480 nm to 600 nm.

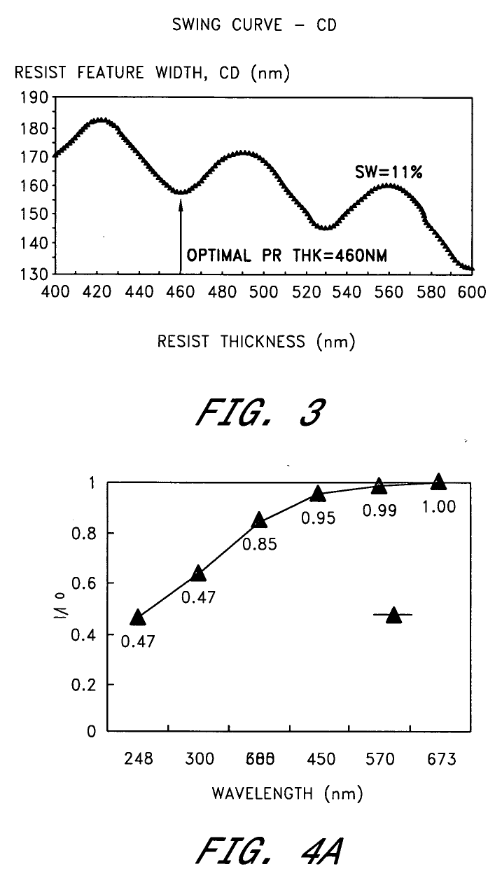

The improved absorption performance of the SSDARC film relative to the standard DARC film is illustrated by FIGS. 4A-4B. FIG. 4A illustrates the amount of transmittance or light transmission I/I_{O} (where I_{O} is the intensity of light entering the film and I is the intensity of light exiting the film) for an example standard DARC at a variety of different wavelengths. FIG. 3B illustrates the amount of light transmission I/I_{O} for an example SSDARC at a variety of different wavelengths. In this example, for the standard DARC, the ratio of I/I_{O} is about 0.47 for at 248 nm. By contrast, referring to FIG. 4B, for the SSDARC the ratio of I/I_{O} is about 0.09 at 248 nm (although other example SSDARC films can provide different ratios of I/I_{O)}, less than 20% that of the standard DARC. Other embodiments can have different ratios of I/I_{O}, such as a ratio of 0.1 at 248 nm, or a ratio of less than 0.09 at 248 nm.

The following table illustrates example concentrations for an example embodiment of the Si-rich DARC layer, as compared to some example conventional concentrations in units of atomic percentage.

| | H | C | N | O | F | Cl | Si |
|---|---|---|---|---|---|---|---|
| Standard | 13.4 | 0.03 | 15.7 | 28 | 0.006 | 0.0005 | 42.8635 |
| DARC | | | | | | | |
| SSDARC | 10.9 | 0.01 | 6.2 | 4.8 | 0.002 | 0.0002 | 78.0878 |

Thus, as illustrated, the Si to O ratio of the standard DARC is 42.8635 to 28 (˜1.5). By comparison, the ratio of Si to O in the silicon enriched DARC is 78.0878 to 4.8 (˜16). Other embodiments of the SSDARC can have an Si/O ratio of between about 10-15, or 15-20, or greater. While in this example the super-Si Rich SiON is over 78% of the total concentration somewhat lower or higher Si concentrations can be used as well, such as, without limitation 65%, 68%, 70%, 75%, 82% or still higher percentages. The second DARC layer can have a lower Si concentration, such as on the order of 35%-55%. Other embodiments of the second DARC can have an Si/O ratio of between about 1.5-2.

The film can be formed in accordance with the following example process parameters, although other parameters can be used as well:

PECVD (Plasma Enhanced Chemical Vapor Deposition): SiH₄/N₂O/He or N₂;

Power: 100˜2000 Watts;

Baking Temperature: 300˜500° C.;

Pressure: 0.1˜20 torr;

SiH₄/O₂/N₂;

TEOS/O₂;

Total gas flow: 50˜10000 sccm.

By way of further example, the film can be formed in accordance with the following example parameters, although other parameters can be used as well:

PECVD: SiH₄(207)/N₂O(96)/He(1900);

Temperature (400° C.);

Deposition (reaction) Time (DT) (8s);

SSDARC thickness (300 Å);

Power (120 W);

Pressure (5.5 torr).

In addition, the following are achieved using the example process described above:

gas flow ratio: SiH4/NO2O>2

Si/O ratio>10

k (extinction coefficient)>1.65

RI (real part of the refractive index n)>2.0

Other embodiments can provide a somewhat smaller gas flow ratio, a somewhat lower Si/O ratio, k value, and RI value.

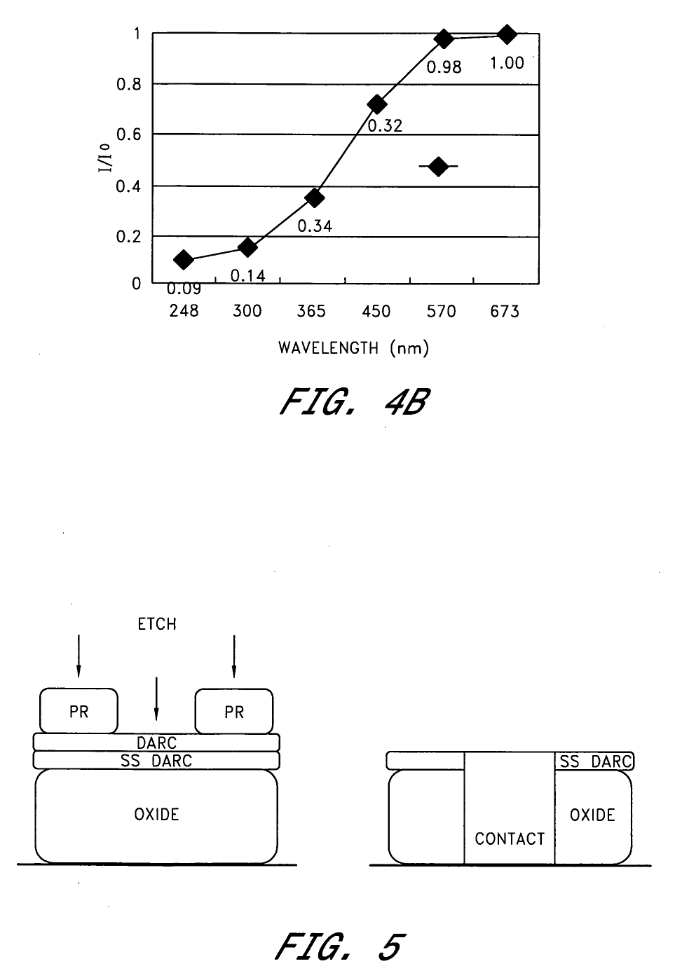

For example, as illustrated in FIG. 5, when forming a contact, a film waiting for patterning is deposited on a substrate, such as a silicon or a polysilicon substrate. A first DARC has a high ratio of high Si to O ratio and/or a high k (extinction coefficient), and/or a high n. Thus, the first DARC acts as a light absorption layer. A second, optional antireflective layer, having a lower or conventional Si to O ratio, can then be deposited thereon to reduce reflections as similarly described above with respect to FIG. 1. Then an etching process is performed to form the contact.

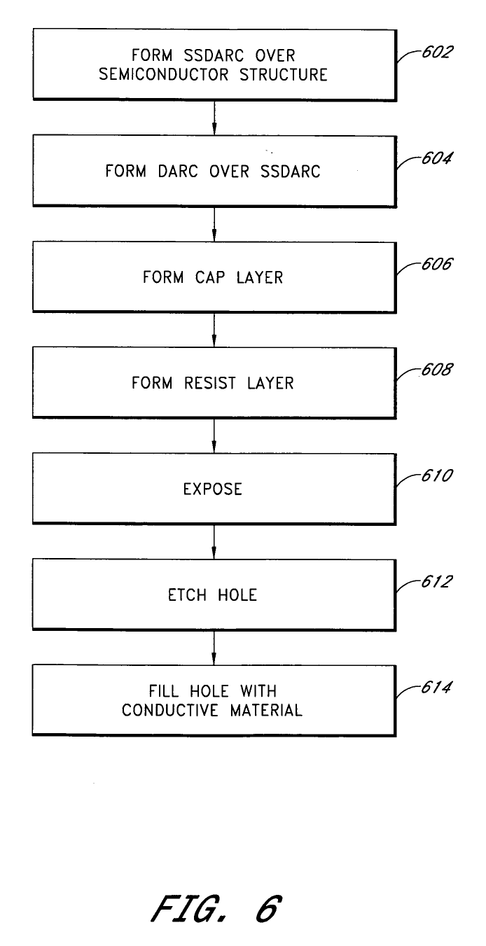

FIG. 6 illustrates an example fabrication process. At state 602, a dielectric layer can be formed over a semiconductor structure and an SSDARC can be formed over the dielectric layer. The SSDARC layer can have a thickness of about 10 nm to 80 nm, with an index of refraction of about 1.9 to 2.4 at a wavelength of 248 nm, a coefficient of extinction of 1.65 or greater, or within the range of 1.5 to 1.9. By way of example, the SSDARC layer can have higher Si concentrations than certain conventional DARC layers.

For example, one embodiment provides Si and O concentrations within the following ranges: (68%<Si<87%; 4.2%<O<5.4%) At state 604, a DARC layer having a lower Si concentration is formed over the SSDARC layer using PECVD, wherein the DARC layer has a thickness of about 20 nm to 45 nm. By way of example, the DARC layer can have lower Si concentrations, such as, by way of illustration: (37%<Si<48%; 24%<O<32%). At state 606, an optional cap layer is formed. At state 608, a photoresist layer is formed over the cap layer. At state 610, the photoresist is then exposed using, for example, deep UV light. At state 612, an etch process is performed and contact hole is formed thereby. The photoresist layer is then removed using dry/wet strip, solvent or otherwise. At state 614, a metal contact or interconnection is then formed within the contact hole. By way of example, the contact opening can be a dual damascene shaped opening and the interconnection can be a dual damascene interconnection. The SSDARC has a lower etch rate that can protect the bottom film.

The foregoing processes can be used with a wide variety of semiconductor applications, including memory circuits, products and the like.

Those of ordinary skill in the art will appreciate that the methods and designs described above have additional applications, and that the relevant applications are not limited to those specifically recited above. Also, the present invention can be embodied in other specific forms without departing from the essential characteristics as described herein. The embodiments described above are to be considered in all respects as illustrative only, and not restrictive in any manner.

What is claimed is:

1. A semiconductor device, comprising:
a substrate;
an Si rich dielectric light absorption layer having an Si concentration of at least 68%; and
a dielectric antireflective coating layer.

2. The semiconductor device as defined in claim 1, wherein the Si-rich dielectric light absorption layer has an extinction coefficient of at least 1.68.

3. The semiconductor device as defined in claim 1, wherein the Si-rich dielectric light absorption layer has an Si concentration of at least 70%.

4. The semiconductor device as defined in claim 1, wherein the Si-rich dielectric light absorption layer has an Si concentration at least 1.5 times the Si concentration of the dielectric antireflective coating layer.

5. The semiconductor device as defined in claim 1, wherein the Si-rich dielectric light absorption layer has concentrations of O, C, F, and Cl.

6. The semiconductor device as defined in claim 1, wherein the Si-rich dielectric light absorption layer is silicon oxynitride.

7. The semiconductor device as defined in claim 1, wherein the Si-rich dielectric light absorption layer is silicon oxide.

8. The semiconductor device as defined in claim 1, wherein the Si-rich dielectric light absorption layer acts as an etch stop layer.

9. The semiconductor device as defined in claim 1, wherein the Si-rich dielectric light absorption has a less than 11% swing ratio.

10. The semiconductor device as defined in claim 1, wherein a stack including the Si-rich dielectric light absorption layer and the dielectric antireflective coating layer has a reflectivity of less than 1%.

11. The semiconductor device as defined in claim 1, wherein a stack including the Si-rich dielectric light absorption layer and the dielectric antireflective coating layer has a reflectivity of less than 0.003.

12. The semiconductor device as defined in claim 1, wherein the Si-rich light absorption coating layer has an Si/O ratio in the range of 10 to 15.

13. The semiconductor device as defined in claim 1, wherein the Si-rich light absorption coating layer has an Si/O ratio in the range of 15 to 25.

14. The semiconductor device as defined in claim 1, wherein the Si-rich light absorption coating layer has an Si/O ratio of at least 10 and the dielectric antireflective coating layer has an Si/O ratio less than 2.

15. The semiconductor device as defined in claim 1, wherein the Si-rich dielectric light absorption layer has a refractive index greater than 2.

16. The semiconductor device as defined in claim 1, wherein the Si-rich dielectric light absorption layer has a refractive index of at least 2.4.

17. The semiconductor device as defined in claim 1, wherein the Si-rich dielectric light absorption layer has a ratio of I/I_{O} of 0.1 or less.

18. The semiconductor device as defined in claim 1, wherein the Si-rich dielectric light absorption layer is formed using plasma enhanced chemical vapor deposition.

19. The semiconductor device as defined in claim 1, wherein the Si-rich dielectric light absorption layer is an ultraviolet light absorption layer.

20. The semiconductor device as defined in claim 1, wherein the Si-rich dielectric light absorption layer is formed using a TEOS/O₂ process.

21. The semiconductor device as defined in claim 1, wherein the Si-rich dielectric light absorption layer has a thickness within the range of 440 nm to 480 nm.

22. The semiconductor device as defined in claim 1, wherein the Si-rich dielectric light absorption layer.

23. The semiconductor device as defined in claim 1, further comprising a cap oxide layer.

24. The semiconductor device as defined in claim 1, wherein the dielectric antireflective coating layer has an Si concentration less than 55%.

25. The semiconductor device as defined in claim 1, wherein the dielectric antireflective coating layer has an Si concentration less than 45%.

26. A semiconductor device, comprising:
a substrate; and
a dielectric light absorption layer having an Si concentration of at least 70%.

27. The semiconductor device as defined in claim 26, further comprising a photoresist layer.

28. The semiconductor device as defined in claim 26, wherein the Si-rich dielectric light absorption layer has an extinction coefficient of at least 1.68.

29. The semiconductor device as defined in claim 26, wherein the Si-rich dielectric light absorption layer has an Si concentration of at least 75%.

30. The semiconductor device as defined in claim 26, wherein the Si-rich dielectric light absorption layer has an Si concentration of at least 78%.

31. The semiconductor device as defined in claim 26, further comprising a second dielectric antireflective coating layer, wherein the Si-rich dielectric light absorption layer has an Si concentration at least 1.5 times the Si concentration of the dielectric antireflective coating layer.

32. The semiconductor device as defined in claim 26, wherein the Si-rich dielectric light absorption layer is silicon oxynitride.

33. The semiconductor device as defined in claim 26, wherein the Si-rich dielectric light absorption layer is silicon oxide,

34. The semiconductor device as defined in claim 26, wherein the Si-rich dielectric light absorption layer acts as an etch stop layer.

35. The semiconductor device as defined in claim 26, wherein the Si-rich dielectric light absorption layer has swing ratio no greater than 11%.

36. The semiconductor device as defined in claim 26, wherein a stack including the Si-rich dielectric light absorption layer and a dielectric antireflective coating layer has a reflectivity of less than 1%.

37. The semiconductor device as defined in claim 26, wherein the Si-rich light absorption coating layer has a Si/O ratio equal or greater than fifteen.

38. The semiconductor device as defined in claim 26, wherein the Si-rich light absorption coating layer has a Si/O ratio equal or greater than ten.

39. The semiconductor device as defined in claim 26, wherein the Si-rich dielectric light absorption layer has a refractive index greater than 2.

40. The semiconductor device as defined in claim 26, wherein the Si-rich dielectric light absorption layer has an extinction coefficient greater than 1.65.

41. The semiconductor device as defined in claim 26, wherein the Si-rich dielectric light absorption layer has a transmittance less than 0.1.

42. The semiconductor device as defined in claim 26, wherein the Si-rich dielectric light absorption layer is formed using plasma enhanced chemical vapor deposition.

43. The semiconductor device as defined in claim 26, wherein the Si-rich dielectric light absorption layer is an ultraviolet light absorption layer.

44. The semiconductor device as defined in claim 26, wherein the Si-rich dielectric light absorption layer is formed using a TEOS/O₂ process.

45. The semiconductor device as defined in claim 26, wherein the Si-rich dielectric light absorption layer has a thickness within the range of 440 nm to 480 nm.

46. The semiconductor device as defined in claim 26, further comprising an inter-layer dielectric.

47. The semiconductor device as defined in claim 26, further comprising an inter-metal dielectric.

48. A method of fabricating a semiconductor device, comprising:
forming a semiconductor structure;
forming an Si-rich light absorption layer having an Si concentration of at least 68%;
forming a photoresist layer over the Si-rich light absorption layer;
exposing the photoresist layer to form a first photoresist opening;
forming an opening in the Si-rich light absorption layer through the photoresist opening; and
filling the Si-rich light absorption layer opening with a conductor.

49. The method as defined in claim 48, further comprising forming a dielectric antireflective coating layer over the Si-rich light absorption layer.

50. The method as defined in claim 48, wherein the photoresist layer is exposed using deep ultraviolet light.

51. The method as defined in claim 48, wherein the Si-rich dielectric light absorption layer has an extinction coefficient of at least 1.68.

52. The method as defined in claim 48, wherein the Si-rich dielectric light absorption layer has an Si concentration of at least 75%.

53. The method as defined in claim 48, wherein the Si-rich dielectric light absorption layer has an Si concentration of at least 78%.

54. The method as defined in claim 48, further comprising forming a dielectric antireflective coating layer over the Si-rich dielectric light absorption layer, wherein the Si-rich dielectric light absorption layer has an Si concentration at least 1.5 times the Si concentration of the dielectric antireflective coating layer.

55. The method as defined in claim 48, wherein the Si-rich dielectric light absorption layer is silicon oxynitride.

56. The method as defined in claim 48, wherein the Si-rich dielectric light absorption layer is silicon oxide.
